(19) United States
(12) Patent Application Publication
(10) Pub. No.: US 2010/0165568 A1
(43) Pub. Date: Jul. 1, 2010

(54) AIRFLOW CONDUCTING APPARATUS

(75) Inventors: HO-CHIN TSAI, Tu-Cheng (TW); LUNG-SHENG TSAI, Tu-Cheng (TW); LI-PING CHEN, Tu-Cheng (TW); YI-LUNG CHOU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/406,190

(22) Filed: Mar. 18, 2009

(30) Foreign Application Priority Data
Dec. 31, 2008 (CN) 200820303967.7

(51) Int. Cl. H05K 7/20

(52) U.S. Cl. 361/679.49; 361/694

(57) ABSTRACT

An airflow conducting apparatus is used for dissipating heat from at least one memory module received in a corresponding socket on a motherboard. The airflow conducting apparatus includes an airduct and a valve piece. The airduct is positioned over the socket and configured to guide air to flow therethrough. The valve piece is attached to an inside of the airduct. The valve piece includes a plurality of parallel elastic flaps. Each flap has at least one configuration that deflects air flowing through the airduct.

### CROSS-REFERENCE TO RELATED APPLICATIONS

Relevant subject matter is disclosed in a co-pending U.S. patent application Ser. No. 11/845102, filed on Aug. 27, 2007, titled “AIRFLOW-GUIDING DEVICE AND COMPUTER HAVING SAME”.

### BACKGROUND

1. Technical Field

The present invention relates to an airflow conducting apparatus and, more particularly, to an airflow conducting apparatus for dissipating heat from memory modules of a computer.

2. Description of Related Art

An airflow conducting apparatus is usually used in a computer or server to dissipate heat generated from heat generating elements. A typical airflow conducting apparatus used to guide airflow generated from a fan, includes a frame body enclosing the fan, and a cover defining a passage way.

In practical applications, when the typical airflow conducting apparatus is used to dissipate heat from memory modules of a computer, the number of used memory modules varies. Drawing heat away from areas where there are no memory modules decreases airflow efficiency in the airflow conducting apparatus.

Therefore, a new airflow conducting apparatus is desired to overcome the above-described shortcoming.

### BRIEF DESCRIPTION OF THE DRAWINGS

FIG. 1 is an exploded isometric view of one embodiment of an airflow conducting apparatus for memory modules on a motherboard, the airflow conducting apparatus includes an airduct and a valve piece;

FIG. 2 is an isometric view of the valve piece of FIG. 1;

FIG. 3 is an assembled isometric view of the airflow conducting apparatus of FIG. 1, shown without the airduct;

FIG. 4 is a sectional view of the airflow conducting apparatus of FIG. 1; and

FIG. 5 is an assembled isometric view of the airflow conducting apparatus of FIG. 1.

### DETAILED DESCRIPTION OF THE EMBODIMENTS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

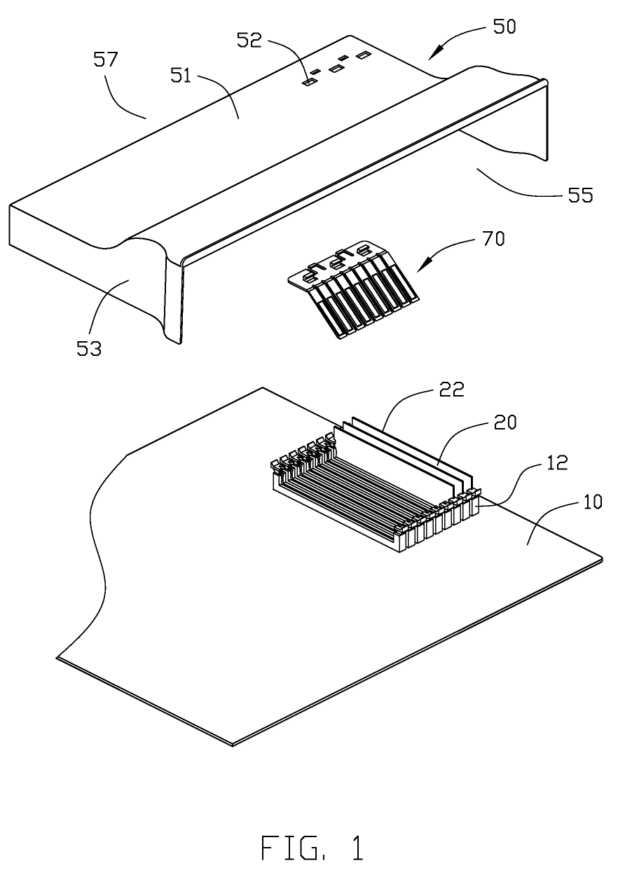

Referring to FIG. 1, one embodiment of an airflow conducting apparatus is configured to guide airflow to dissipate heat from a plurality of memory modules 20 on a motherboard 10. The airflow conducting apparatus includes an airduct 50 and an adjustable valve piece 70. The motherboard 10 includes a plurality of sockets 12 to receive the memory modules 20. Each memory module 20 includes a top surface 22 that partially supports the adjustable valve piece 70 when the adjustable valve piece 70 is coupled to the motherboard 10.

The airduct 50 includes a top wall 51, and a pair of side walls 53 extending substantially perpendicularly from the top wall 51. A plurality of holes 52 is defined in the top wall 51. The top wall 51 and the side walls 53 cooperatively define an airflow passage. An inlet 55 and an outlet 57 are defined on opposite sides of the airduct 50 to communicate with the airflow passage.

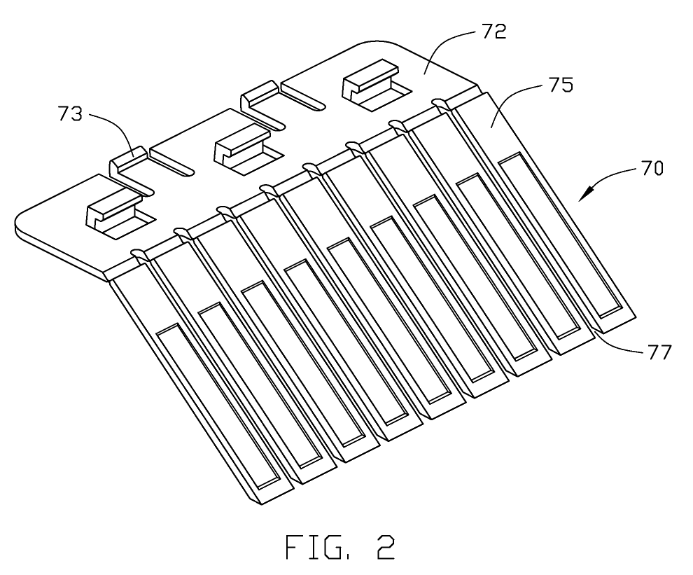

Referring also to FIG. 2, the valve piece 70 may be made from polypropylene. The valve piece 70 includes a fixing portion 72 and a plurality of substantially parallel elastic flaps 75 extending from an end of the fixing portion 72. A plurality of hooks 73 protrudes from the fixing portion 72 corresponding to the holes 52 of the top wall 51. A gap 77 is defined between each adjacent flaps 75.

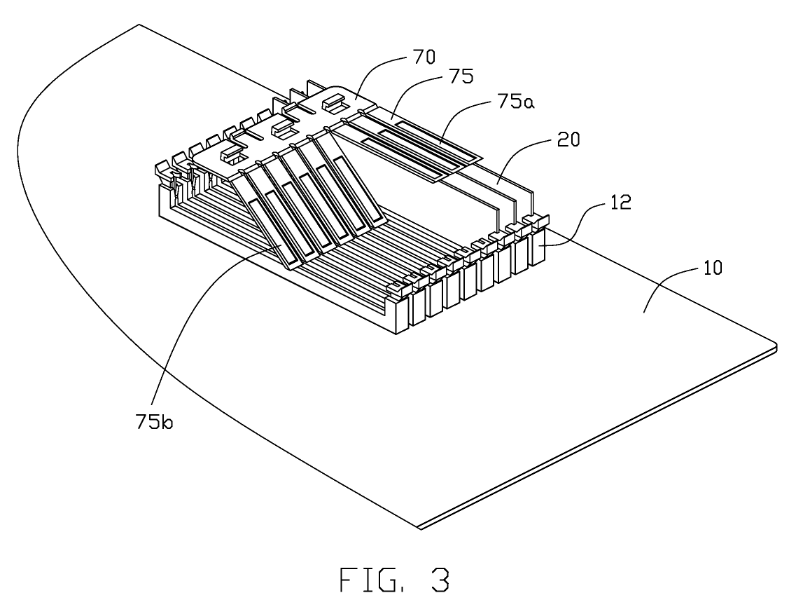

Referring to FIG. 3, the airduct 50 is omitted to clearly illustrate one embodiment of the airflow conducting apparatus. The valve piece 70 is mounted to an inner surface of the top wall 51 of the airduct 50 such that the flaps 75 extend outwardly and the hooks 73 extend into the holes 52. A number of memory modules 20 are shown coupled in the corresponding sockets 12. The sockets 12 are covered by the airduct. A first group of the flaps 75 that are aligned with the memory modules 20 abuts the memory modules 20 and becomes flattened between the top surface 22 of the memory modules 20 and the top wall 51, thereby yielding opened flaps 75a. A width of each flap 75 is larger than a width of the top surface 22 of each memory module 20. A second group of the flaps 73 that are not aligned with the memory modules 20, substantially remains unchanged and dips towards the sockets 12 without the memory modules 20, thereby yielding closed flaps 75b.

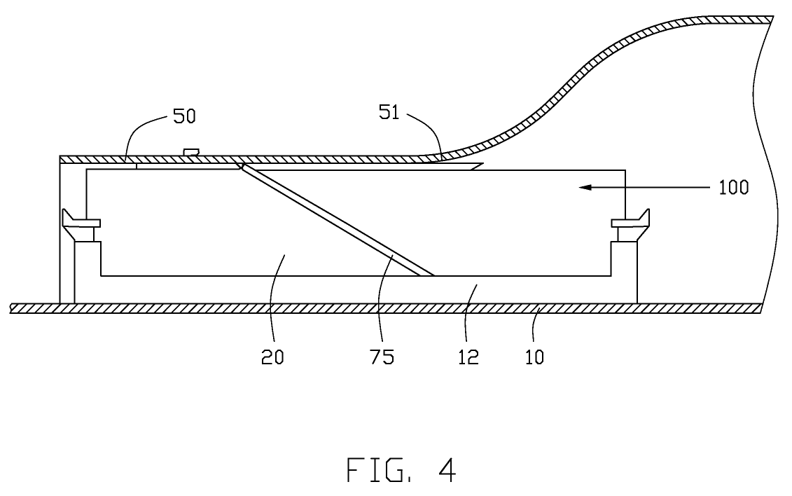

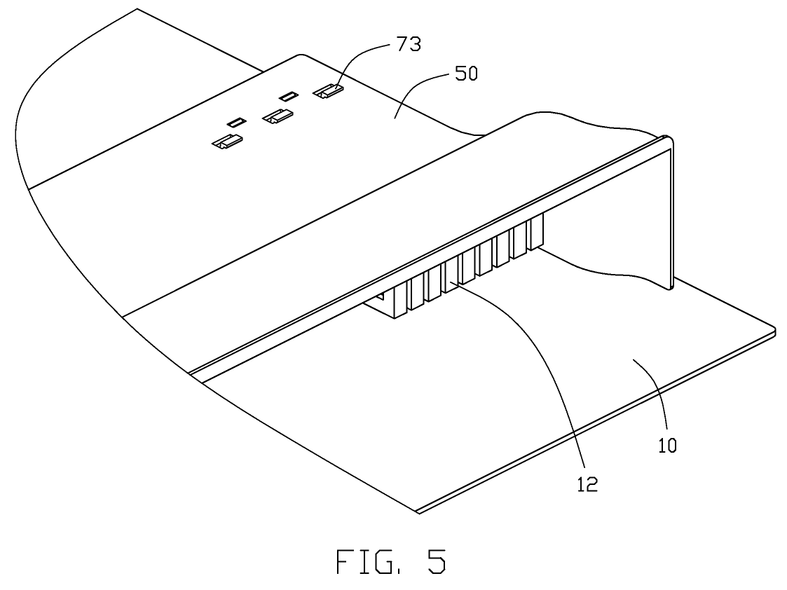

Referring also to FIG. 4 and FIG. 5, when using the airflow conducting apparatus to dissipate heat from the memory modules 20, airflow 100 is guided into the airduct 50 via the inlet 55. When the airflow 100 travels to the memory modules 20, the airflow 100 dissipates heat from the memory modules 20. When the airflow 100 travels to the sockets 12 without the memory modules 20, the airflow 100 is partially deflected by the flaps 75b towards the memory modules 20 to enhance the heat dissipating efficiency. Thus, the airflow conducting apparatus efficiently uses the airflow 100 to dissipate heat from the memory modules 20.

It is to be understood, however, that even though numerous characteristics and advantages of the present embodiments have been set forth in the foregoing description, together with details of the structure and function of the embodiments, the disclosure is illustrative only, and changes may be made in detail, especially in matters of shape, size, and arrangement of parts within the principles of the embodiments to the full extent indicated by the broad general meaning of the terms in which the appended claims are expressed.

1. An airflow conducting apparatus for dissipating heat from at least one memory module received in a corresponding socket on a motherboard, the airflow conducting apparatus comprising:
an airduct positioned over the socket and configured to guide air to flow therethrough, a plurality of holes defined in the airduct; and
a valve piece attached to an inside of the airduct, the valve piece comprising a plurality of substantially parallel elastic flaps and hooks, each flap having at least one configuration that deflects air flowing through the airduct, each hook extends into a corresponding one of the plurality of holes.

2. The airflow conducting apparatus of claim 1, wherein each flap is aligned with the socket such that when the at least one memory module is installed in the corresponding socket, a corresponding flap is deflected by a top surface of the corresponding memory module.

3. The airflow conducting apparatus of claim 1, wherein a width of each flap is larger than a width of a top surface of each memory module.

4. The airflow conducting apparatus of claim 1, wherein the flaps extend from one side of the valve piece.

5. The airflow conducting apparatus of claim 4, wherein each flap dips towards the socket in the original state configuration.

6. The airflow conducting apparatus of claim 1, wherein the airduct comprises a top wall and a pair of side walls extending substantially perpendicularly from the top wall; the valve piece is attached to an inner surface of the top wall.

7. The airflow conducting apparatus of claim 1, wherein each flap is made from polypropylene.

8. A computer comprising:
a motherboard comprising a socket arranged along a first direction;
a memory module received in the socket; and
a valve piece comprising a first elastic flap, the first flap positioned at a lateral side of the memory module having at least one configuration that deflects air flowing along the first direction towards the memory module;
wherein the valve piece further comprises a second flexible flap, and the second flap is deformed to a planar shape by a top surface of the memory module.

9. The computer of claim 8, wherein the valve piece further comprises a second elastic flap having at least one configuration that deflects air flowing along the first direction towards the memory module; the second flap is deformed by a top surface of the memory module.

10. The computer of claim 9, wherein a width of the first flap is larger than a width of a top surface of the memory module.

11. The computer of claim 8, wherein the first flap and the second flap are made from polypropylene.

12. The computer of claim 8 further comprising an airduct positioned over the socket and configured to guide air to flow therethrough; the valve piece is attached to an inner side of the airduct.
